(19) United States
(12) Patent Application Publication
(10) Pub. No.: US 2026/0324480 A1
(43) Pub. Date: Oct. 15, 2026

(54) BONDING APPARATUS, BONDING METHOD, STORAGE MEDIUM, AND METHOD FOR MANUFACTURING ARTICLE

(71) Applicant: CANON KABUSHIKI KAISHA, Tokyo (JP)

(72) Inventors: TETSUNARI IDA, Tochigi (JP); AKIFUMI KOMUKAI, Tochigi (JP)

(21) Appl. No.: 19/637,972

(22) Filed: Apr. 2, 2026

(30) Foreign Application Priority Data
Apr. 9, 2025 (JP) 2025-064310

(51) Int. Cl. H10W 72/00; H10W 80/00

(52) U.S. Cl. CPC H10W 72/07173; H10W 72/07183; H10W 80/161

(57) ABSTRACT

A bonding apparatus configured to bond dies to corresponding ones of a plurality of bonding target regions on a wafer includes a bonding head group including a plurality of bonding heads configured to hold the dies, a holding unit configured to hold the wafer, and a control unit configured to control a relative position between the bonding head group and the holding unit. The control unit controls bonding such that the plurality of bonding heads included in the bonding head group bond the dies to corresponding ones of the plurality of bonding target regions based on combinations of bonding heads and bonding target regions according to a relative amount of movement between the bonding head group and the holding unit in a plane parallel to a surface of the wafer having the plurality of bonding target regions.

### BACKGROUND

### Field of the Technology

The present disclosure relates to a bonding apparatus, a bonding method, a storage medium, and a method for manufacturing an article.

### Description of the Related Art

Japanese Patent Laid-Open No. 2023-77928 discloses a bonding apparatus for bonding dies held by bonding heads to a wafer.

When a plurality of bonding heads perform bonding at mutually different timings, combinations of bonding heads and bonding target regions on a wafer affect throughput.

### SUMMARY

The present disclosure is directed to providing a bonding apparatus that is advantageous in terms of throughput.

According to an aspect of the present disclosure, there is provided a bonding apparatus configured to bond dies to corresponding ones of a plurality of bonding target regions on a wafer. The bonding apparatus includes a bonding head group including a plurality of bonding heads configured to hold the dies, a holding unit configured to hold the wafer, and a control unit configured to control a relative position between the bonding head group and the holding unit. The control unit controls bonding such that the plurality of bonding heads included in the bonding head group bond the dies to corresponding ones of the plurality of bonding target regions based on combinations of bonding heads and bonding target regions according to a relative amount of movement between the bonding head group and the holding unit in a plane parallel to a surface of the wafer having the plurality of bonding target regions.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram of a bonding apparatus.

FIG. 2A is a schematic diagram of a head configured to hold a die.

FIG. 2B is a schematic diagram of a head configured to hold a die.

FIG. 3 is a schematic diagram of a wafer stage.

FIG. 4 is a flowchart of a bonding method.

FIG. 5 is a diagram illustrating a wafer on which a bonding process has been partially completed.

FIG. 6 is a diagram illustrating an example in which a bonding head is retracted from a wafer in the Z-axis direction.

FIG. 7 is a diagram illustrating an example in which a bonding head is retracted from a wafer along the X-Y plane.

FIG. 8 is a diagram illustrating an example of the bonding order of bonding target regions on a wafer.

FIG. 9 is a schematic diagram illustrating bonding target regions on a wafer W, and a first bonding head and a second bonding head disposed over a die measuring unit for measuring the dies.

FIG. 10 is a flowchart of a method for manufacturing an article.

### DESCRIPTION OF THE EMBODIMENTS

Embodiments of the present disclosure will be described hereinbelow with reference to the drawings. It should be understood that the following embodiments are not intended to limit the disclosure as set forth in the claims. Although the embodiments describe a plurality of features, not all of the plurality of features are essential to the disclosure, and the embodiments may be combined as appropriate. In the drawings, the same or similar components are denoted by the same reference numerals, and duplicate descriptions are omitted.

In this specification and the drawings, directions are indicated by an X-Y-Z coordinate system in which the X-, Y-, and Z-axes are orthogonal to each other. In this coordinate system, the vertical direction is defined as the Z-axis direction, and a horizontal plane perpendicular to the vertical direction is defined as the X-Y plane. However, when the X-Y-Z coordinate system is illustrated in drawings, that coordinate system takes precedence.

In each embodiment, a specific configuration will be described.

### First Embodiment

In the following description, a wafer on which a semiconductor device is formed is described as a bonding target object, and a singulated die including a semiconductor device is described as a bonding object. However, the bonding target object and the bonding object are not limited thereto, and various modifications are possible within the scope of the disclosure.

Examples of the bonding target object include, but are not limited to, a silicon wafer, a silicon wafer on which wiring is formed, a glass wafer, a glass panel on which wiring is formed, a printed wiring board (PWB) on which wiring is formed, a printed circuit board (PCB) on which electronic components are mounted, and a metal panel. Alternatively, the bonding target object may be a wafer on which a semiconductor device is formed and to which a die having a semiconductor device formed thereon is bonded. Alternatively, the bonding target object may be, not a wafer, but a die having a semiconductor device formed thereon.

For example, the bonding object may include, but is not limited to, a single singulated die, a stack of a plurality of singulated dies, a small piece of material, an optical element, a microelectromechanical system (MEMS), or other structures. The die is singulated through a die dicing process (cutting process).

The bonding method is not limited to any particular bonding method. Examples of the bonding method include, but are not limited to, adhesive bonding, temporary bonding using a temporary adhesive, hybrid bonding, atomic diffusion bonding, vacuum bonding, and bump bonding. Various temporary bonding methods and permanent bonding methods may be used.

Hybrid bonding, also referred to as direct bonding, is a bonding method in which a bonding object and a bonding target object are directly bonded without using wires, adhesives, or the like. One example of hybrid bonding will be simply described. First, bonding surfaces of a bonding object and a bonding target object are each cleaned, and then the bonding surfaces are rendered hydrophilic and activated, for example, by plasma treatment. Then, the activated bonding surfaces of the bonding object and the bonding target object are brought into contact with each other and are temporarily bonded together. Thereafter, the bonding object and the bonding target object are permanently bonded by, for example, heat treatment. Hybrid bonding offers advantages in improving electrical characteristics and enhancing performance. For example, hybrid bonding can increase data transmission speed between semiconductor devices, thereby significantly enhancing the performance of a device as a whole. Another advantage of hybrid bonding is that dies can be stacked, thereby enabling efficient use of space. This enables manufacture of compact, high-performance devices.

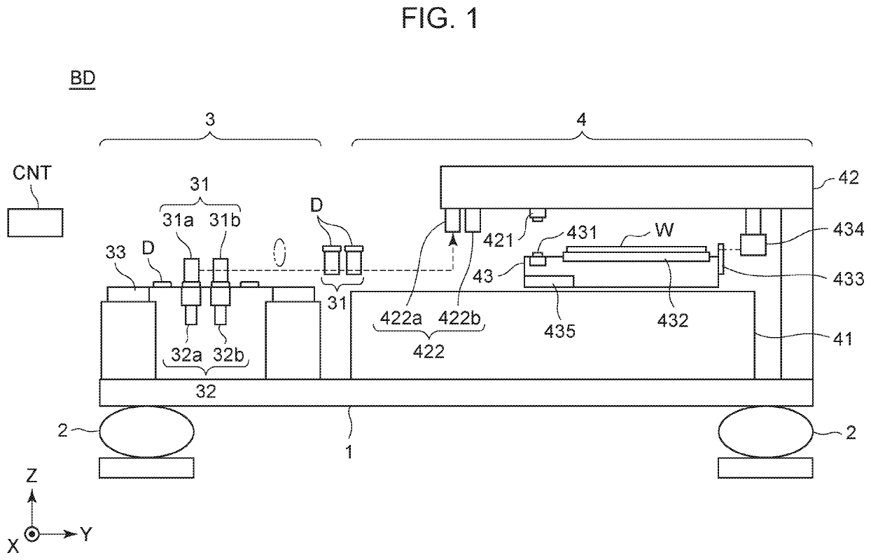

FIG. 1 is a schematic diagram of a bonding apparatus BD. As illustrated in FIG. 1, the bonding apparatus BD may include a pick-up unit 3 and a bonding unit 4 disposed on a base 1 that is vibration-damped by mounts 2. Although FIG. 1 shows an example in which the pick-up unit 3 and the bonding unit 4 are mounted on a single base 1, the pick-up unit 3 and the bonding unit 4 may be individually mounted on separate bases. The bonding apparatus BD may be configured to position and bond dies D on bonding target portions of a wafer W serving as a bonding target object. The dies D may be provided in a state in which the dies D are held by a dicing tape attached to a dicing frame 33. The bonding apparatus BD may further include a control unit CNT configured to control the pick-up unit 3 and the bonding unit 4. The control unit CNT may be implemented by, for example, a programmable logic device (PLD) such as a field-programmable gate array (FPGA), an application-specific integrated circuit (ASIC), a general-purpose or dedicated computer having a program incorporated, or any combination thereof.

The pick-up unit 3 may include a pick-up head 31 and a release head 32.

The pick-up unit 3 separates a die D to be bonded to the wafer W from the dicing tape by using the release head 32, and holds the die D by suction using the pick-up head 31. The pick-up head 31 rotates the die D by, for example, 180 degrees, and transfers the die D to the bonding head 422 of the bonding unit 4.

The bonding apparatus BD of the present embodiment includes a plurality of pick-up heads 31a and 31b, a plurality of release heads 32a and 32b, and a plurality of bonding heads 422a and 422b. The plurality of bonding heads are collectively referred to as a bonding head group.

In other words, the bonding head group includes a plurality of bonding heads. In the example shown in FIG. 1, two pick-up heads, two release heads, and two bonding heads are provided. However, the numbers of the pick-up heads, the release heads, and the bonding heads may be different from one another, and each number may be three or more. Thus, by providing a plurality of pick-up heads, release heads, and bonding heads, the time required for bonding processing can be reduced. Here, the number of pick-up heads is, for example, equal to or greater than the number of bonding heads.

The pick-up head 31 comes into contact with the bonding surface of the die D. Accordingly, in applications to a bonding method in which bonding is performed after surface activation, such as hybrid bonding, the pick-up head 31 preferably has a highly stable surface. Having a highly stable surface means, for example, that a surface of the pick-up head 31 that comes into contact with the bonding surface of the die D is coated with diamond-like carbon (DLC), fluorine-based coating, or the like. Alternatively, in applications to a bonding method in which bonding is performed after surface activation, such as hybrid bonding, it is preferable to reduce a contact area by employing a shape having a small contact area, such as a high-density pin shape. Alternatively, in applications to a bonding method in which bonding is performed after surface activation, such as hybrid bonding, it is preferable that the pick-up head 31 employ a non-contact handling method, such as a Bernoulli chuck. Alternatively, in applications to a bonding method in which bonding is performed after surface activation, such as hybrid bonding, the pick-up head 31 may be configured to hold a side surface or an edge portion of the die D so as not to come into contact with a bonding surface of the die D.

The bonding unit 4 may include a surface plate 41 and a support portion 42. A wafer stage 43 may be disposed over the surface plate 41. The wafer stage 43 may be driven in the X-axis direction (a first direction) and the Y-axis direction (a second direction) by a driving mechanism 435 such as a linear motor.

The driving mechanism 435 may also be configured to rotate the wafer stage 43 about an axis parallel to the Z-axis direction (a third direction). Instead of the driving mechanism 435 rotating the wafer stage 43 about the axis parallel to the Z-axis direction, the bonding head 422 may rotate the die D about the axis parallel to the Z-axis direction. The driving mechanism 435 serves as a positioning mechanism for changing the relative position between a wafer chuck 432 (or the wafer W) and the bonding head 422 (or the die D).

A die measuring unit 431 is disposed on the wafer stage 43. The die measuring unit 431 may be, for example, an image capturing unit (a camera), and is configured to detect, by imaging, the position of a feature portion of the die D held by the bonding head 422. The wafer stage 43 may be provided with a bar mirror 433. The bar mirror 433 may be used as a target of an interferometer 434. The wafer stage 43 may include the wafer chuck 432 mounted thereon. The wafer chuck 432 holds the wafer W serving as a bonding target object. The wafer stage 43 functions as a support portion configured to support the wafer chuck 432 and the die measuring unit 431.

A wafer measuring unit 421 is disposed on the support portion 42. The wafer measuring unit 421 is, for example, an image capturing unit (a camera). The wafer measuring unit 421 detects, by imaging, the position of a feature portion of the wafer W serving as a bonding target object held by the wafer chuck 432.

The control unit CNT may be configured to specify or calculate positions of a plurality of bonding target portions on the wafer W based on the position of the feature portion of the wafer W detected by the wafer measuring unit 421. The support portion 42 may further include the interferometer 434 configured to measure the position of the wafer stage 43 using the bar mirror 433. The support portion 42 may further include a bonding head 422 configured to receive and hold a die D transferred from the pick-up head 31 and to bond the die D to a bonding target portion of the wafer W. The support portion 42 functions as a support portion for supporting the bonding head 422 and the wafer measuring unit 421.

In the example of FIG. 1, the pick-up head 31 rotates the die D by 180 degrees and transfers the die D to the bonding head 422. Alternatively, a first die holding unit and a second die holding unit may be provided, and the die D may be transferred from the pick-up head 31 to the first die holding unit, then from the first die holding unit to the second die holding unit, and thereafter from the second die holding unit to the bonding head 422. Alternatively, a driving mechanism for driving the bonding head 422 may be provided, thereby driving the bonding head 422 so as to receive the die D. Alternatively, the pick-up head 31 may place the die D on an intermediate stage provided on the wafer stage 43, and the bonding head 422 may hold the die D on the intermediate stage by operation of the driving mechanism included in the wafer stage 43 or by operation of the bonding head 422. In this case, while the die D is placed on the intermediate stage, the wafer measuring unit 421 may detect the position of the feature portion of the die D.

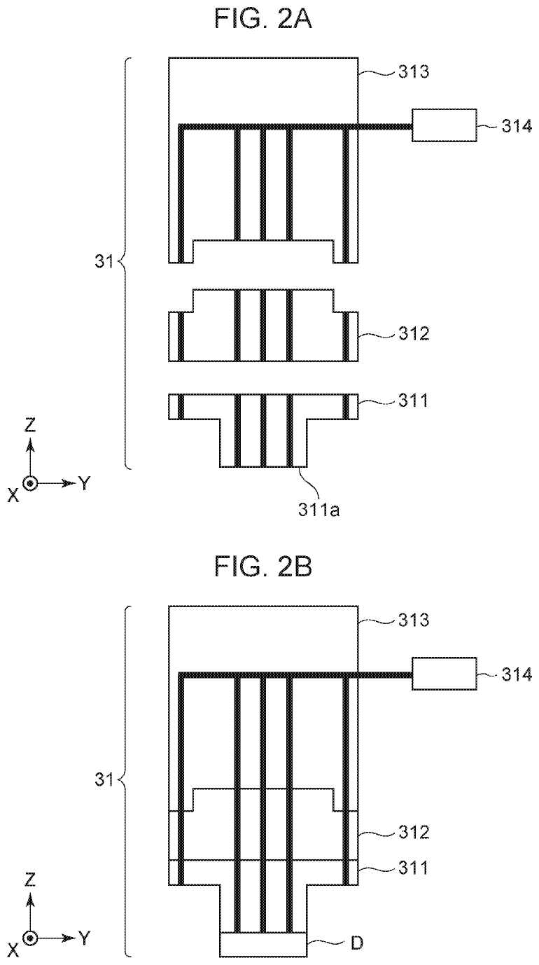

FIGS. 2A and 2B are schematic diagrams of a head that holds the die D. In the examples illustrated in FIGS. 2A and 2B, the pick-up head 31 is shown as an example; however, the bonding head 422 may have a similar configuration. A head configured to hold the die D includes a collet holder 312 configured to hold a collet 311 and a main body 313 configured to hold the collet holder 312. The collet holder 312 holds the collet 311, which is a jig that comes into contact with the die D. FIG. 2A illustrates a state in which the collet 311, the collet holder 312, and the main body 313 are not integrated. FIG. 2B illustrates a state in which the collet 311, the collet holder 312, and the main body 313 are integrated. When a bonding process is performed, the collet 311, the collet holder 312, and the main body 313 are integrated, as illustrated in FIG. 2B.

Holding of the collet holder 312 by the main body 313 and holding of the collet 311 by the collet holder 312 are performed, for example, by evacuating gas from a space between the holding member and the held member using a vacuum source 314. Holding of the collet holder 312 by the main body 313 and holding of the collet 311 by the collet holder 312 may be performed by mechanical holding using claws or other mechanisms, or by magnetic holding using a magnet.

The collet 311 holds the die D with a holding surface 311a. Examples of materials used for the collet include, but are not limited to, fluoro-rubber, polyether ether ketone (PEEK), and stainless steel (SUS). Holding of the die D using the collet 311 is performed by, for example, evacuating gas from a space between the holding surface 311a and the die D.

The collet holder 312 is held by the main body 313 at all times. In contrast, the collet 311 may be replaced depending on the type of the die D. Alternatively, the collet 311 may be replaced depending on damage, wear, or contamination that occurs during bonding a plurality of dies D.

For example, when the collet 311 is replaced in accordance with the occurrence of damage or contamination, a used collet is discarded into a collet disposal unit (not shown), and a new collet supplied from a collet supply unit (not shown) is installed on the collet holder 312. Removal and installation of the collet 311 at this time are performed using, for example, a collet replacing hand (not shown). The collet 311 may be cleaned as appropriate, and the bonding apparatus BD may include a unit for cleaning the collet 311.

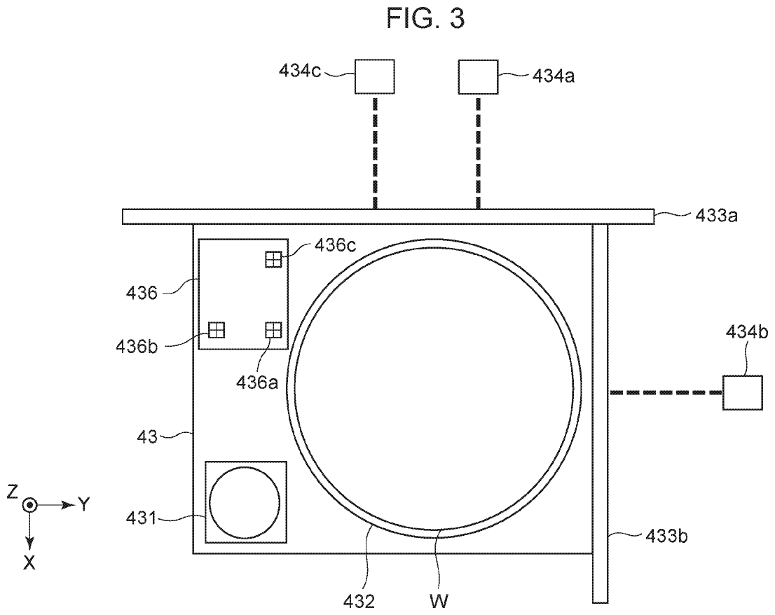

FIG. 3 is a schematic diagram of the wafer stage 43. The wafer W is held by the wafer chuck 432. The wafer W or the wafer stage 43 may be positioned with respect to rotation about axes parallel to the X-axis direction (first direction) and the Y-axis direction (second direction), which are orthogonal to or intersect with each other, and about an axis parallel to the Z-axis direction (third direction) that is orthogonal thereto. For this purpose, the wafer stage 43 may be provided with the bar mirror 433, more specifically, bar mirrors 433a and 433b.

The bar mirror 433a functions as a target for the interferometers 434a and 434c. The control unit CNT is configured to detect the position of the wafer stage 43 in the X-axis direction based on an output from the interferometer 434a, and to detect rotation of the wafer stage 43 about an axis parallel to the Z-axis direction based on outputs from the interferometers 434a and 434c. The bar mirror 433b functions as a target for the interferometer 434b. The control unit CNT is configured to detect the position of the wafer stage 43 in the Y-axis direction based on an output from the interferometer 434b. The control unit CNT may be configured to perform feedback control of the position of the wafer W or the wafer stage 43 with respect to rotation about axes parallel to the X-axis direction and the Y-axis direction, and rotation about an axis parallel to the Z-axis direction orthogonal thereto, based on outputs from the interferometers 434a, 434b, and 434c. The interferometer 434 and the control unit CNT may be regarded as components of the above-described positioning mechanism.

A reference plate 436 may be provided on the upper surface of the wafer stage 43. A plurality of marks 436a, 436b, and 436c may be disposed on the reference plate 436. The reference plate 436 may be formed of a material having a low coefficient of thermal expansion, thereby allowing marks to be formed with high positional accuracy. In one example, the reference plate 436 may be configured by forming marks on a quartz substrate using a semiconductor lithography process. The reference plate 436 may have a surface at substantially the same height as the surface of the wafer W and may be observed using the wafer measuring unit 421; however, a separate camera for observing the reference plate 436 may also be provided. The wafer stage 43 has a configuration in which a coarse-motion stage driven over a large range and a fine-motion stage driven over a small range with high precision are combined. In such a configuration, the die measuring unit 431, the bar mirrors 433a and 433b, the wafer chuck 432, and the reference plate 436 may be provided on the fine-motion stage to achieve high-precision positioning.

Hereinafter, a method for ensuring the origin position, magnification, X-axis and Y-axis directions (rotation), and orthogonality of the wafer stage 43 using the reference plate 436 will be described. The mark 436a is observed by the wafer measuring unit 421, and an output value of the interferometer when the mark 436a is positioned at the center of an output image of the wafer measuring unit 421 is defined as the origin of the wafer stage 43. Next, the mark 436b is observed by the wafer measuring unit 421, and the Y-axis direction (rotation) of the wafer stage 43 and magnification in the Y-axis direction are determined based on an output value of the interferometer when the mark 436b is positioned at the center of an output image of the wafer measuring unit 421. Next, the mark 436c is observed by the wafer measuring unit 421, and the X-axis direction (rotation) of the wafer stage 43 and magnification in the X-axis direction are determined based on an interferometer output value when the mark 436c is positioned at the center of an output image of the wafer measuring unit 421. Thus, calibration of axis directions and orthogonality can be performed by defining the direction from the mark 436b to the mark 436a on the reference plate 436 as the Y-axis of the bonding apparatus BD, and defining the direction from the mark 436c to the mark 436a as the X-axis of the bonding apparatus BD. Furthermore, calibration can be performed by using the spacing between the mark 436b and the mark 436a as a scale reference for the Y-axis of the bonding apparatus BD, and by using the spacing between the mark 436c and the mark 436a as a scale reference for the X-axis of the bonding apparatus BD. Since the refractive index of the optical path of an interferometer changes due to atmospheric pressure variations or temperature fluctuations, measured values of the interferometer may fluctuate. For this reason, it is preferable to perform calibration at any time to ensure the origin position, magnification, rotation, and orthogonality of the wafer stage 43. To reduce fluctuations in measured values of the interferometer, it is preferable to enclose a space in which the wafer stage 43 is disposed in a temperature-regulated chamber, thereby controlling the temperature inside the temperature-regulated chamber.

Although an example of calibration using a reference plate has been described, a calibration method is not limited to this example. For example, calibration may be performed by performing an abutment operation against a reference surface, or high-precision positioning may be performed using a position measuring device having an absolute reference, such as a white-light interferometer.

The position of the wafer stage 43 may be measured using an encoder. Specifically, instead of the interferometer and the bar mirror, an encoder scale and an encoder head may be disposed. The encoder scale is preferably formed of a material having a low coefficient of thermal expansion. In one example, the encoder scale may be produced by forming a scale on a quartz substrate using a semiconductor lithography process. Alternatively, a plurality of encoder heads may be disposed, and the encoder heads to be used may be switched depending on the position of the bonding target portion. Alternatively, a pair of encoder heads may be disposed symmetrically with respect to the bonding target portion, which is advantageous for improving position measurement accuracy.

In the example illustrated in FIG. 1, the wafer stage 43 moves on the X-Y plane; alternatively, the bonding head 422 may move on the X-Y plane, or both the wafer stage 43 and the bonding head 422 may move on the X-Y plane. When the bonding head 422 moves, it is preferable to provide a measuring mechanism (an interferometer or an encoder) for measuring the position of the bonding head 422. In the present embodiment, the X-Y plane is a plane parallel to a surface of the wafer W including a bonding target region.

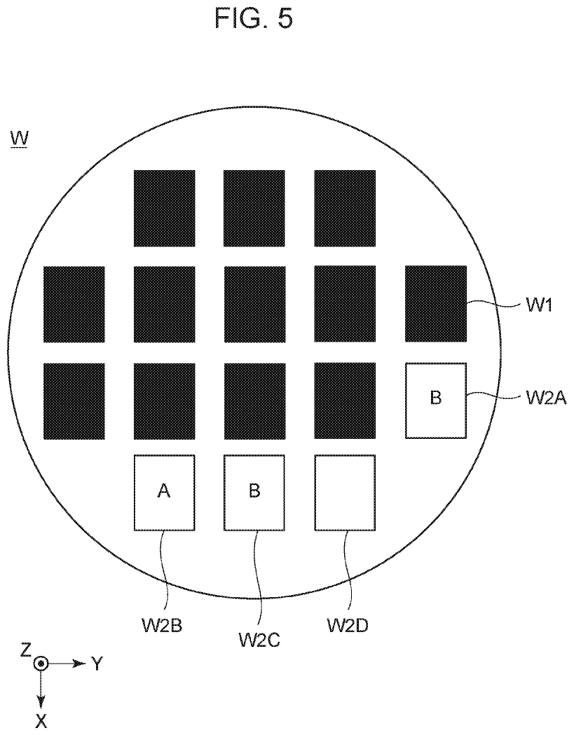

When a bonding process is performed using a plurality of bonding heads 422, it may be undesirable for the plurality of bonding heads 422 to simultaneously perform the bonding process. FIG. 5 is a diagram illustrating a wafer W on which a bonding process has been partially completed. Black regions on the wafer W are bonding-completed regions W1 in which bonding of dies D has been completed, and the white regions on the wafer W are bonding-target regions W2 (W2A, W2B, W2C, and W2D) in which bonding of dies D has not been completed. Now consider a configuration in which a next bonding-target region is W2A, and a first bonding head (a first holding unit) and a second bonding head (a second holding unit) are arranged side by side in the Y-axis direction. In this case, only one of the first bonding head and the second bonding head can face the bonding-target region, and the other cannot face the bonding-target region. In other words, the first holding unit and the second holding unit cannot perform a bonding process simultaneously. If a die D held by one holding unit is bonded to the bonding-target region W2A, a die D held by the other holding unit comes into contact with the wafer W or the wafer chuck 432. Then, the die D that has come into contact with the wafer W or the wafer chuck 432 is damaged.

Furthermore, a first die held by the bonding head 422a (first holding unit) and a second die held by the bonding head 422b (second holding unit) may have different thicknesses. In such a case, when the first holding unit and the second holding unit perform bonding simultaneously, a contact time between the bonding target object and the first die differs from a contact time between the bonding target object and the second die, which may result in improper bonding of at least one of the first die and the second die. Alternatively, the height of a first bonding target region on the wafer W to which the first die is to be bonded may differ from the height of a second bonding target region on the wafer W to which the second die is to be bonded. In such a case, when the first holding unit and the second holding unit perform bonding simultaneously, a contact time between the first bonding target object and the first die differs from a contact time between the second bonding target object and the second die, which may result in improper bonding of at least one of the first die and the second die. Furthermore, the type and rank (quality) of a die held by the first holding unit may be appropriate for the first bonding target region, and the type and rank (quality) of a die held by the second holding unit may be inappropriate for the second bonding target region. In such a case, bonding is performed simultaneously by the first holding unit and the second holding unit, the improper die may be bonded to the second bonding target region.

In the above case, it is preferable to perform control such that a plurality of bonding heads perform bonding simultaneously, and control such that one bonding head is retracted while the other bonding head performs bonding. The control such that a plurality of bonding heads perform bonding simultaneously refers to control such that a time during which the first die held by the first holding unit is in contact with a bonding target object and a time during which the second die held by the second holding unit is in contact with a bonding target object overlap with each other at least in part. In other words, the bonding apparatus according to the present embodiment switches between a first control and a second control during a bonding process. The first control controls the bonding such that a time during which the first die held by the first bonding head is in contact with the wafer W and a time during which the second die held by the second bonding head is in contact with the wafer W overlap with each other at least in part. The second control controls the bonding such that the first die held by the first bonding head does not come into contact with the wafer W while the second die held by the second bonding head is in contact with the wafer W. In the first control, timings at which the first die held by the first bonding head and the second die held by the second bonding head start to come into contact with the wafer W may be the same.

When a plurality of bonding heads perform bonding at mutually different timings, combinations of bonding heads and bonding target regions on the wafer W affect throughput.

The present disclosure provides a bonding apparatus that is advantageous in terms of throughput. Specifically, combinations of bonding heads and bonding target regions are determined in view of throughput. For example, a moving distance of the wafer stage 43 when the first bonding head performs a bonding process on the first bonding target region and the second bonding head performs a bonding process on the second bonding target region is defined as a first moving distance. A moving distance of the wafer stage 43 when the second bonding head performs a bonding process on the first bonding target region and the first bonding head performs a bonding process on the second bonding target region is defined as a second moving distance. Since a shorter moving distance of the wafer stage 43 in a bonding process is more advantageous in terms of throughput, employing a method corresponding to the second moving distance when the second moving distance is shorter than the first moving distance is advantageous in terms of throughput. In other words, it is advantageous to perform a bonding process on the first bonding target region by the second bonding head and to perform a bonding process on the second bonding target region by the first bonding head. In this case, combinations of bonding heads and bonding target regions on the wafer W are determined such that the second bonding head performs a bonding process on the first bonding target region, and the first bonding head performs a bonding process on the second bonding target region. Although the moving distance of the wafer stage 43 has been described above, combinations may be determined based on relative movement amounts between the bonding head group 422 and the wafer stage 43, instead of the moving distance of the wafer stage 43.

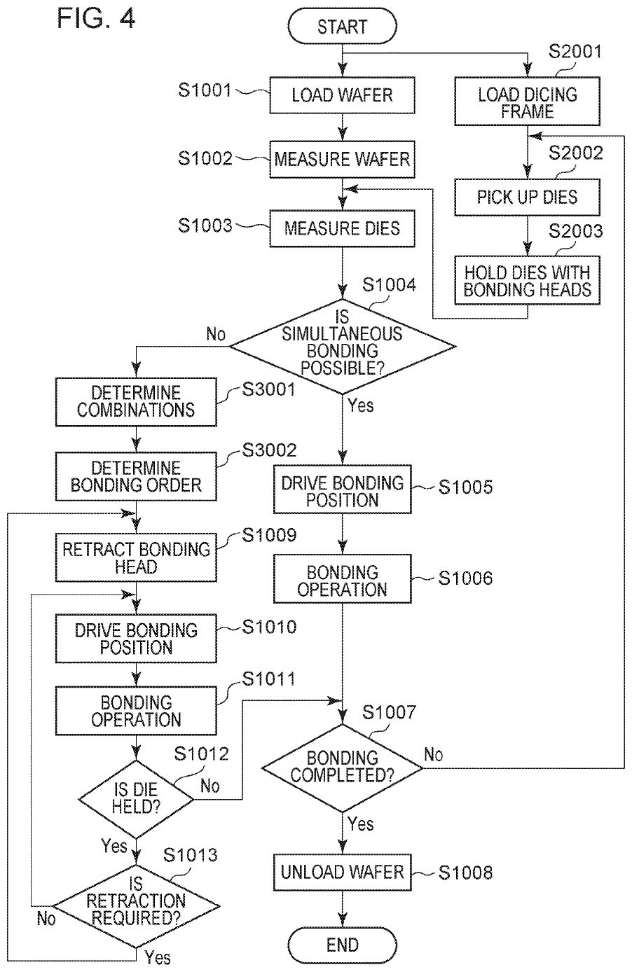

FIG. 4 is a flowchart of a bonding method. This bonding method is controlled by the control unit CNT. The bonding method shown in the flowchart of FIG. 4 is performed by the control unit CNT in accordance with a program stored therein. In step S1001, the wafer W, which serves as a bonding target object, is loaded into the bonding apparatus BD and held by the wafer chuck 432. Since foreign matter adhering to a bonding surface may cause bonding defects, the interior of the bonding apparatus BD may be configured as a space having a high level of cleanliness, for example, Class 1. To maintain a high cleanliness level, the wafer W may be housed in a container having high airtightness and maintained at a high cleanliness level, such as a front opening unified pod (FOUP), and may be loaded into the bonding apparatus BD from the container. To increase the cleanliness level, the wafer W may be cleaned in the bonding apparatus BD after being loaded therein. Furthermore, pre-processing for bonding may also be performed. Examples of the pre-processing may include, but are not limited to, cleaning of the wafer W and the dies D, application of an adhesive to the wafer W in the case of adhesive bonding, and activation of the surface of the wafer W in the case of hybrid bonding. The wafer W is roughly positioned by a pre-aligner (not shown) based on a notch or an orientation flat and a wafer outer profile, and is then conveyed to and held by the wafer chuck 432 on the wafer stage 43.

In step S1002, the position of a feature portion (measurement target portion) of the wafer W is measured using the wafer measuring unit 421, and the position of the bonding target portion is determined based thereon. Here, the positional relationship (relative position) between the feature portion (measurement target portion) of the wafer W and the bonding target portion is known. Focus adjustment for capturing an image of the feature portion of the wafer W using the wafer measuring unit 421 may be performed by a focus adjustment mechanism provided in the wafer measuring unit 421. Alternatively, focus adjustment may be performed by a Z-axis driving mechanism provided in the wafer stage 43, which drives the wafer W in the Z-axis direction. Alignment marks are often formed on the wafer W; however, when no alignment mark is formed, a feature portion whose position can be specified may be measured. The control unit CNT may cause the wafer measuring unit 421 to capture an image of the feature portion of the wafer W, and may detect a relative position of the image of the feature portion with respect to the center of an output image of the wafer measuring unit 421 as the position of the feature portion (measurement target portion).

An offset amount may be determined in advance to enable high-accuracy measurement of the relative position of the marks with respect to a reference point of the bonding apparatus BD. This process may include driving the wafer stage 43 so that a mark on the reference plate 436 is positioned within a field of view of the wafer measuring unit 421, and measuring the position of the mark using the wafer measuring unit 421. The offset amount with respect to a position measured using the wafer measuring unit 421 can be determined based on the driven position of the wafer stage 43 and the position of the mark measured using the wafer measuring unit 421. Here, although the reference point of the bonding apparatus BD is generally set at a specific mark position of the reference plate 436, any other position serving as the reference position may be used.

Because a measurement range in the rotational orientation of the interferometer or the encoder is limited, a rotation amount correctable by the wafer stage 43 is small. For this reason, when the rotation amount of the wafer W is large, it is preferable to correct the rotation and re-hold the wafer W. When the wafer W is re-held, it is necessary to measure the position of the wafer W again. The surface position (surface height) of the bonding surface of the wafer W is measured during an auto-focus operation performed when measuring the marks on the wafer W, or by using a first height measuring unit (not shown). Because the thickness of the wafer W varies, it is advantageous to measure the surface position of the wafer W in order to accurately manage the gap between the wafer W and the die D during a bonding operation. Here, the measurement result of the surface height of the bonding surface of the wafer W is stored in a storage unit (not shown) included in the control unit CNT.

Since the origin position, magnification, X-axis and Y-axis directions (rotation), and orthogonality of the wafer stage 43 are ensured by using the reference plate 436, the position of the feature portion (measurement target portion) of the wafer W may be measured with reference to the origin position and the X-axis and Y-axis of the wafer stage 43. The wafer W includes bonding target portions (or semiconductor devices serving as bonding targets) arranged at a predetermined pitch.

Because these bonding target portions (semiconductor devices) are manufactured by a semiconductor manufacturing apparatus with high-accuracy positioning of a plurality of layers, the bonding target portions (semiconductor devices) are repeatedly arranged at a pitch having nano-level accuracy. For this reason, wafer alignment in step S1002 may not require measuring the positions of feature portions corresponding to all bonding target portions (semiconductor devices). Accordingly, the control unit CNT may be configured to perform a process (a first measuring step) of determining the positions of a plurality of bonding target portions by measuring the positions of measurement target portions fewer than the number of bonding target portions and statistically processing the measurement results. Here, the plurality of measurement target portions may be determined based on arrangement information of the semiconductor devices. In order to determine the positions of the plurality of bonding target portions, the control unit CNT calculates, based on measurement results of the positions of the plurality of measurement target portions, the origin position of the repeated arrangement of a plurality of bonding target portions, rotation amounts in the X-axis and Y-axis directions, orthogonality between the X-axis and the Y-axis, and a magnification error of the repetition pitch.

The wafer chuck 432 preferably has a temperature regulation function for regulating the temperature of the wafer W. This is because the coefficient of thermal expansion of a silicon wafer is 3 ppm/°C, and in the case of a wafer having a diameter of 300 mm, when the temperature increases by 1 °C, a position at an outermost periphery of the wafer may shift by 150 mm×0.000003=0.00045 mm, that is, 450 nm. If the bonding position shifts after wafer alignment, bonding cannot be performed with high positional accuracy; therefore, the temperature of the wafer is preferably stabilized within 0.1 °C

Hereinafter, movement of a die to be bonded in parallel with or subsequent to loading of a wafer serving as a bonding target object and wafer alignment will be described. In step S2001, the dicing frame 33, in which dies D singulated by a dicer are arranged on a dicing tape, is conveyed into the bonding apparatus BD. Since foreign matter adhering to a bonding surface may cause bonding defects, the dicing frame 33 may be conveyed using a container having high airtightness and maintained at a high cleanliness level. To increase the cleanliness level, the dies D on the dicing frame 33 may be cleaned in the bonding apparatus BD. The dicing frame 33 may be roughly positioned in terms of its rotational orientation and shift position by a pre-aligner (not shown) based on an outer-shape reference of the dicing frame 33.

Furthermore, the dies D may be sorted as a pre-processing step. In this sorting, the dies D may be sorted, for example, by type or quality (rank). The sorting is performed based on arrangement information of the bonding target regions of the wafer W or quality information of the dies D.

In step S2002, the dies D are picked up by the plurality of pick-up heads 31. In other words, each of the plurality of pick-up heads 31 holds a corresponding die D. Specifically, the pick-up head 31 and the release head 32 may be positioned at the position of a die D to be picked up. Then, while the die D to be picked up is being sucked by the pick-up head 31, the dicing tape is peeled off from the die D by the release head 32, whereby the die D is held by the pick-up head 31. The die D to be picked up may be determined based on, for example, known good die (KGD) information transmitted online to the bonding apparatus BD. In general, only known good dies are picked up; however, when a known bad die (KBD) is to be bonded to a defective device portion of the wafer W, the known bad die is picked up.

The pick-up operation may be performed based on type information of the die D. For example, when a plurality of types of dies D are held on the dicing frame 33, a die D of a type to be bonded to the bonding target region of the wafer W is picked up. Alternatively, the pick-up operation may be performed based on quality information of the die D. For example, a die D of quality suitable for the bonding target region of the wafer W is picked up. For example, when a die D is to be bonded to the bonding target region of a high-quality wafer W, the pick-up operation is performed such that a high-quality die D is bonded.

In step S2003, the plurality of dies D picked up by the plurality of pick-up heads 31 are conveyed to the plurality of bonding heads 422, and each of the dies D is held by a corresponding bonding head 422. When the dies D are picked up by the pick-up heads 31, the semiconductor device surfaces face the pick-up heads 31. In contrast, the dies D are conveyed to the bonding heads 422 such that surfaces opposite to the semiconductor device surfaces face the bonding heads 422. The conveying of the dies D to the bonding heads 422 may be performed directly by the pick-up heads 31 or may be performed via a plurality of die holding units. Pre-processing for bonding may be performed while the dies D are being conveyed. Examples of the pre-processing may include, but are not limited to, cleaning of the dies D, application of an adhesive in the case of adhesive bonding, and surface activation in the case of hybrid bonding. If the surface activity becomes inactive while the dies D are conveyed to the bonding heads 422, a process of activating the bonding surfaces is preferably performed using an atmospheric-pressure plasma activation unit after the bonding heads 422 hold the dies D.

In this manner, the wafer W serving as a bonding target object and the dies D are held by respective holding units. This is a state in which each of the plurality of bonding heads 422 holds a die D.

In step S1003, the positions of the dies D held by the bonding heads 422 may be measured. Specifically, the wafer stage 43 may be driven by the driving mechanism 435 such that feature portions of the dies D are brought into the field of view of the die measuring unit 431. Focus adjustment may be provided by a focus adjustment mechanism provided in the die measuring unit 431, or by a Z-axis driving mechanism provided in the bonding head 422, which drives the die D in the Z-axis. Alternatively, focus adjustment may be provided by a Z-axis driving mechanism provided on the wafer stage 43 on which the die measuring unit 431 is disposed, the Z-axis driving mechanism driving the die measuring unit 431 in the Z-axis direction.

A scribe line on which alignment marks used in a semiconductor manufacturing process are formed may be removed by dicing. Accordingly, the dies D often do not have alignment marks. Therefore, positions may be measured using, as feature portions, ends of pads or bumps arranged on the dies D, regions having an aperiodic arrangement whose positions can be specified, or the outer shapes of the dies D. The control unit CNT causes the die measuring unit 431 to capture images of the dies D and determines the positions of feature portions based on the positions of images of the feature portions relative to the center of an output image of the die measuring unit 431. While it is necessary to manage an offset amount used when positioning the dies D at bonding portions based on the positions of the dies D measured using the die measuring unit 431, a method therefor will be described later.

When the positions of the dies D are measured, it is preferable to measure positions of a plurality of feature portions in the dies D and also measure rotation amounts of the dies D. In order to measure positions of a plurality of feature portions, the wafer stage 43 may be driven each time positions of the feature portions are measured, or the field of view of the die measuring unit 431 may be designed to allow a plurality of feature portions to be observed at a time. The dies D may be rotated by rotating the wafer stage 43 during bonding. However, because the measurement range of the interferometer 434 in the rotational orientation is small, when the rotation amounts of the dies D are large, it is preferable to correct the rotation and re-hold the dies D. When the dies D are re-held, it is necessary to measure positions of the dies D again. A surface position (surface height) of the bonding surface of each die D is measured during an auto-focus operation while a position of the die D is measured, or using a second height measuring unit (not shown). Because the thicknesses of the dies D vary, it is advantageous to measure the surface positions of the dies D in order to accurately manage the gap between the wafer W and the dies D during a bonding operation. Here, the measurement results of the surface heights of the bonding surfaces of the dies D are stored in a storage unit (not shown) included in the control unit CNT. Heights at a plurality of positions of the dies D may be measured, and the orientation of the dies D or the wafer W may be adjusted by a tilt mechanism (not shown) during bonding. Such a tilt mechanism may be incorporated in the wafer stage 43, the wafer chuck 432, or the bonding heads 422.

In step S1004, the control unit CNT determines whether simultaneous bonding by the plurality of bonding heads 422 is possible (a determination step). This is also a step of determining which of the above-described first control and second control is to be performed. In other words, during the bonding step, one of the first control and the second control is performed. The first control controls the bonding such that a time during which the first die held by the first holding unit is in contact with the bonding target object and a time during which the second die held by the second holding unit is in contact with the bonding target object overlap with each other at least in part. The second control controls the bonding such that the first die held by the first holding unit does not come into contact with the bonding target object while the second die held by the second holding unit is in contact with the bonding target object. The determination in step S1004 is performed based on at least one of arrangement information of bonding target regions of the wafer W, information on circuit patterns formed in the bonding target regions, information on types of the dies D, information on quality, information on thickness, and information on bonding history. The information on quality includes information on the quality of at least one of the wafer W and the dies D. The information on thickness includes information on the thickness of at least one of the wafer W and the dies D.

For example, based on arrangement information of bonding target regions on the wafer W (information as illustrated in FIG. 5), the control unit CNT determines whether a plurality of bonding heads can simultaneously perform bonding, that is, whether bonding target regions are present directly below the plurality of bonding heads. When bonding target regions are present directly below the plurality of bonding heads, the control unit CNT determines that simultaneous bonding by the plurality of bonding heads 422 is possible. When no bonding target region is present directly below any one of the plurality of bonding heads during a bonding process, the control unit CNT determines that simultaneous bonding by the plurality of bonding heads 422 is not possible. In other words, when no bonding target region corresponding to the first die held by a first bonding head is present on the wafer W and a bonding target region corresponding to the second die held by the second bonding head is present on the wafer W, the control unit CNT performs the second control.

In another example, based on information on circuit patterns formed in bonding target regions or information on the types of the dies D, the control unit CNT determines whether a plurality of bonding heads can simultaneously perform bonding. In other words, the control unit CNT determines whether each bonding head holds a die D of a type suitable for the bonding target region. When each of the dies D held by the plurality of bonding heads is of a type to be bonded to a corresponding bonding target region, the control unit CNT determines that simultaneous bonding by the plurality of bonding heads 422 is possible. When any one of the dies D held by the plurality of bonding heads is not of a type to be bonded to a corresponding bonding target region, the control unit CNT determines that simultaneous bonding by the plurality of bonding heads 422 is not possible. In the example shown in FIG. 5, a case in which it is determined whether two bonding heads can simultaneously perform bonding on the bonding target regions W2B and W2C will be described. It is assumed that a die of type A is to be bonded to the bonding target region W2B, and that a die of type B is to be bonded to the bonding target region W2C. In this case, if both of the two bonding heads hold dies of type B, a die of the desired type cannot be bonded to the bonding target region W2B. In that case, the control unit CNT determines that simultaneous bonding by the plurality of bonding heads is not possible. In other words, when the first die is not of a type corresponding to the first bonding target region on the wafer W and the second die is of a type corresponding to the second bonding target region on the wafer W, the control unit CNT performs the second control. The first die is a die held by the first bonding head, and the second die is a die held by the second bonding head. In addition, a bonding target region for a die that is not bonded at this time may be determined. For example, consider a case in which no die has yet been bonded to the bonding target region W2A and a die of type B is to be bonded to the bonding target region W2A. In such a case, the control unit CNT determines that one of the dies of type B held by the two bonding heads is to be bonded to the bonding target region W2C, and the other is to be bonded to the bonding target region W2A. The information on the circuit patterns formed in the bonding target regions includes table or map information including information on the names of the circuit patterns formed in the bonding target regions or symbols assigned to the bonding target regions. The information on the types of the dies D includes table or map information including information on the names of the dies D or symbols assigned to the dies D. Here, the types of the dies D are classified based on, for example, the types of circuit patterns included in the dies D or the sizes of the dies D.

In another example, based on information on the quality of the bonding target regions on the wafer W or the quality of the dies D, the control unit CNT determines whether the plurality of bonding heads can perform simultaneous bonding, that is, whether the bonding heads hold dies having quality suitable for the bonding target regions. When each of the dies D held by the plurality of bonding heads has quality suitable for being bonded to a corresponding bonding target region, the control unit CNT determines that simultaneous bonding by the plurality of bonding heads 422 is possible. When any one of the dies D held by the plurality of bonding heads has quality that is not suitable for being bonded to a corresponding bonding target region, the control unit CNT determines that simultaneous bonding by the plurality of bonding heads 422 is not possible. In the example shown in FIG. 5, a case in which it is determined whether two bonding heads can simultaneously perform bonding on the bonding target regions W2B and W2C will be described. It is assumed that a die having a quality of rank A is to be bonded to the bonding target region W2B, and a die having a quality of rank B is to be bonded to the bonding target region W2C. In this case, if both of the two bonding heads hold dies of rank B, a die of the desired rank cannot be bonded to the bonding target region W2B. In that case, the control unit CNT determines that simultaneous bonding by the plurality of bonding heads is not possible. In addition, a bonding target region for a die that is not bonded at this time may be determined. For example, consider a case in which no die has yet been bonded to the bonding target region W2A and a die of rank B is to be bonded to the bonding target region W2A. In such a case, the control unit CNT determines that one of the dies of rank B held by the two bonding heads is to be bonded to the bonding target region W2C, and the other is to be bonded to the bonding target region W2A. The information on the quality of the bonding target regions on the wafer W or the quality of the dies D includes table or map information including information on the names of the bonding target regions or the dies D or symbols assigned to the bonding target regions or the dies D. In other words, the control unit CNT performs the second control when the quality of the first die does not correspond to the first bonding target region on the wafer W and the quality of the second die corresponds to the second bonding target region on the wafer W. The first die is a die held by the first bonding head, and the second die is a die held by the second bonding head.

In another example, based on information on the thickness of the wafer W or the thickness of the dies D, the control unit CNT determines whether the plurality of bonding heads can perform simultaneous bonding. The information on the thickness may be obtained by acquiring information measured by another apparatus or may be obtained using the above-described height measuring unit. For example, the thickness of the first die held by the bonding head 422a serving as the first holding unit and the thickness of the second die held by the bonding head 422b serving as the second holding unit may be different from each other. When the thicknesses are different, if the first holding unit and the second holding unit perform bonding simultaneously, a time during which the bonding target object (the wafer W) is in contact with the first die differs from a time during which the bonding target object is in contact with the second die, and as a result, bonding of at least one of the first die and the second die may not be appropriately performed. In such a case, the control unit CNT determines that the plurality of bonding heads cannot perform simultaneous bonding. Furthermore, the thickness of the first bonding target region to be bonded by the first holding unit and the second bonding target region to be bonded by the second holding unit may be different from each other. When the thicknesses are different, if the first holding unit and the second holding unit perform bonding simultaneously, a time during which the bonding target object (the wafer W) is in contact with the first die differs from a time during which the bonding target object is in contact with the second die, and as a result, bonding of at least one of the first die and the second die may not be appropriately performed. In such a case, the control unit CNT determines that the plurality of bonding heads cannot perform simultaneous bonding. The control unit CNT may make the determination based on whether the thickness of the wafer W or the thickness of the dies D falls within a predetermined allowable range. In other words, when at least one of the thickness of the first bonding target region and the thickness of the first die is outside the allowable range, and at least one of the thickness of the second bonding target region and the thickness of the second die is within the allowable range, the control unit CNT performs the second control.

In another example, based on information on bonding history, the control unit CNT determines whether the plurality of bonding heads can perform bonding simultaneously. For example, in the example shown in FIG. 5, a case is described in which a die D has not yet been bonded to the bonding target region W2B, a die D has already been bonded to the bonding target region W2C, and one die D is to be bonded to each of the bonding target regions W2B and W2C.

In this case, the bonding target regions W2B and W2C have different heights. Accordingly, when two bonding heads perform bonding simultaneously, times during which the bonding target regions W2B and W2C are in contact with the die D differ from each other. As a result, bonding to at least one of the bonding target regions W2B and W2C may not be properly performed. In such a case, the control unit CNT determines that simultaneous bonding by the plurality of bonding heads is not possible. In other words, the control unit CNT obtains information on the number of dies D that have already been bonded to the first bonding target region to which the first die held by the first bonding head is to be bonded. Furthermore, the control unit CNT obtains information on the number of dies D that have already been bonded to the second bonding target region to which the second die held by the second bonding head is to be bonded. When the number of dies that have already been bonded to the first bonding target region differs from the number of dies that have already been bonded to the second bonding target region, the control unit CNT performs the second control.

If it is determined in step S1004 that simultaneous bonding by the plurality of bonding heads 422 is possible, the process proceeds to step S1005. In step S1005, the wafer stage 43 is driven by the driving mechanism 435 such that the dies D are positioned at the bonding target regions (bonding target portions) of the wafer W serving as the bonding target object. At this time, the control unit CNT controls the driving mechanism 435 such that the position of the wafer stage 43 is feedback-controlled based on measurement results from the interferometer 434. At this time, the control unit CNT determines the target position of the wafer stage 43 based on the position and rotation amount of the wafer W measured in step S1002, the positions and rotation amounts of the dies D measured in step S1003, and the offset amounts. When shifts occur due to a bonding operation, as will be described later, the control unit CNT considers the shifts as offset amounts. As described above, step S1005 may be performed by driving the bonding heads 422 such that the dies D are positioned at the bonding target regions (bonding target portions) of the wafer W serving as the bonding target object.

In step S1006, the plurality of dies D are bonded to the bonding target regions of the wafer W (bonding step). As a bonding operation, the bonding heads 422 may be moved up and down, or the wafer stage 43 or the wafer chuck 432 may be moved up and down. In other words, the driving mechanism may be driven such that the relative position (spacing) between the die D held by the bonding head 422 and the wafer W held by the wafer chuck 432 changes. In the bonding step of step S1006, the plurality of dies D held by the plurality of bonding heads 422 are bonded to the plurality of bonding target regions of the wafer W by changing the relative positions between the plurality of bonding heads 422 and the wafer W. In other words, the control performed in step S1006 is the first control. The first control controls the bonding such that a time during which the first die held by the first bonding head is in contact with the wafer W and a time during which the second die held by the second bonding head is in contact with the wafer W overlap with each other at least in part.

In the bonding operation, a plurality of types of dies D may be bonded to a single wafer W, different dies D may be bonded to respective bonding target regions on the wafer W, or different numbers of dies D may be bonded to respective bonding target regions on the wafer W.

In step S1007, the control unit CNT determines whether the bonding of the dies D to the wafer W has been completed. This refers to determining whether bonding of all dies D to be bonded to the wafer W has been completed. For example, consider a case in which, after a die D is bonded to one bonding target region of the wafer W, another die D is further bonded onto the bonded die D. In this case, if the second bonding of the die D to the same bonding target region has not been completed, it is determined in step S1007 that the bonding process has not been completed. If the bonding process has not been completed, the process returns to the pick-up operation for the die D in step S2002. In the example shown in FIG. 4, the determination in step S1007 is performed after the bonding operation in step S1006, and then the pick-up operation for the die D is performed in step S2002. However, the die pick-up operation in step S2002 may be performed in parallel during the period from the measurement of the dies D in step S1003 to the bonding operation in step S1006.

When bonding of the dies D to all of the plurality of bonding target portions of the wafer W has been completed, the wafer W is unloaded from the bonding apparatus BD in step S1008. The wafer W may be returned to the FOUP from which the wafer W was loaded, or may be returned to another container. However, in general, bonding changes the thickness of the wafer W, and therefore it is necessary to increase the spacing between wafers W compared with that before bonding; accordingly, the wafer W is returned to another container.

If it is determined in step S1004 that simultaneous bonding by the plurality of bonding heads 422 is not possible, the control unit CNT selects a bonding head to be used for bonding (a die D to be bonded). In other words, the control unit CNT selects a bonding head to be retracted. This selection is performed based on at least one of arrangement information of bonding target regions of the wafer W, information on circuit patterns formed in the bonding target regions, information on types of the dies D, information on quality, information on thickness, and information on bonding history. The information on quality includes information on the quality of at least one of the wafer W and the dies D. The information on thickness includes information on the thickness of at least one of the wafer W and the dies D. For example, when two of three bonding heads can perform simultaneous bonding and one bonding head cannot perform simultaneous bonding, only the bonding head that cannot perform simultaneous bonding is retracted. Alternatively, when only one of two bonding heads can perform bonding, the other bonding head is retracted. Alternatively, as illustrated in FIG. 5, when bonding is to be performed only on one bonding target region (W2A), bonding heads other than the one bonding head used for bonding among the plurality of bonding heads are retracted.

In the present embodiment, combinations of bonding heads and bonding target regions on the wafer W are determined in step S3001. The details of step S3001 will be described later. After step S3001, a bonding order is determined in step S3002 (order determination step). The details of step S3002 will also be described later. Here, the determination of combinations in step S3001 and the determination of a bonding order in step S3002 are performed during the second control.

Next, the control unit CNT retracts the selected bonding head(s) (hereinafter referred to as “the bonding head”) based on the selection result (S1009). The bonding head is retracted such that, for example, the bonding head to be retracted is driven in the +Z direction to prevent the die D held by the retracted bonding head from coming into contact with other components during a bonding process performed by a bonding head used for bonding. In other words, the bonding head to be retracted is moved in a direction perpendicular to the bonding target surface on the wafer W (the Z-axis direction) and in a direction away from the wafer W (the +Z direction). The amount of movement at this time is, for example, a distance equal to or greater than the sum of the thickness of the first die held by the first bonding head and the thickness of the wafer W. Alternatively, when the bonding head moves in the −Z direction to perform bonding, only a bonding head used for bonding is moved in the −Z direction, and the bonding head to be retracted is not moved in the −Z direction, thereby achieving retraction. In other words, the bonding head to be retracted is maintained at a position farther from the wafer W than the bonding head used for bonding. The bonding head used for bonding is moved in a direction perpendicular to the bonding target surface on the wafer W (the Z-axis direction) and in a direction closer to the wafer W (the −Z direction). Alternatively, the bonding head to be retracted may be moved on the X-Y plane to prevent the die D held by the retracted bonding head from coming into contact with other members during the bonding process performed by the bonding head used for bonding. In other words, the bonding head to be retracted may be moved in a direction parallel to the bonding target surface of the wafer W (in the X-Y plane direction). When the bonding head is retracted by being moved, a driving mechanism for moving the bonding head may be provided. For example, movement of the bonding head in the X-Y plane direction may involve moving the first bonding head to a position at which the first bonding head does not overlap the wafer W when viewed in a direction perpendicular to the bonding target surface of the wafer W (the Z-axis direction). In step S1009, the bonding head to be retracted may be moved in a plurality of directions including a direction perpendicular to the bonding target surface of the bonding target object (the Z-axis direction, the +Z direction) and a direction parallel to the bonding target surface of the bonding target object (a direction in the X-Y plane).

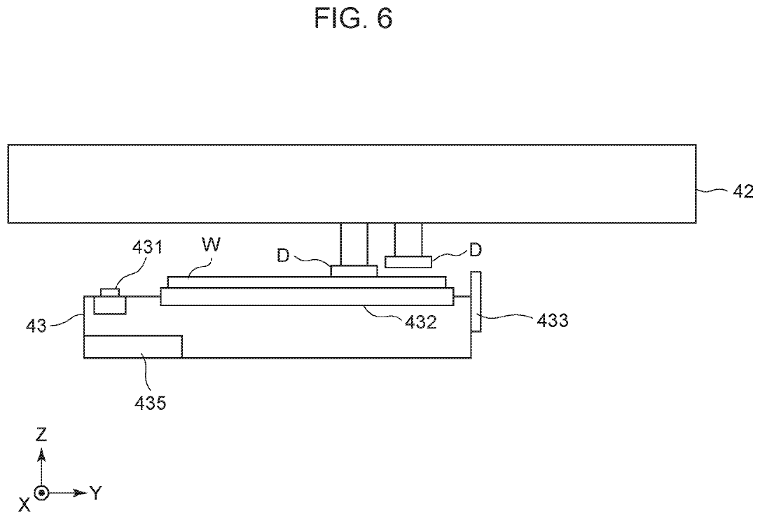

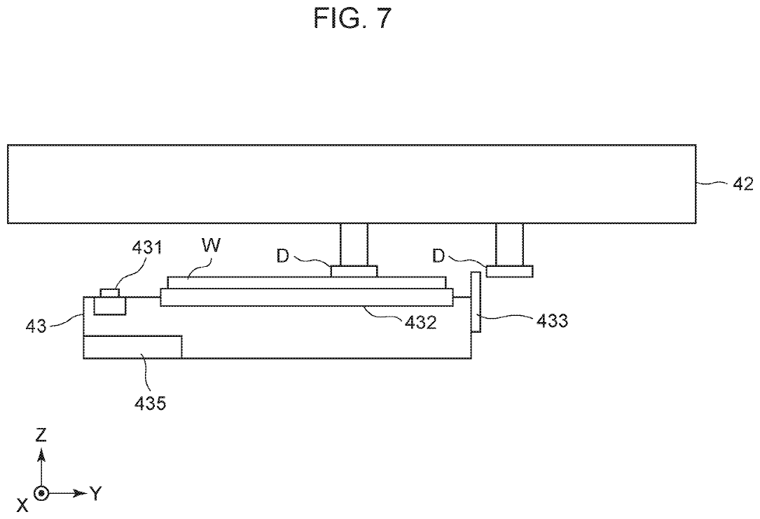

When the wafer W is moved in the +Z direction by driving the wafer stage 43 to perform a bonding process, the distances in the Z-axis direction between the dies D held by the respective bonding heads and the wafer W (the wafer stage 43) change in accordance with the amount of movement of the wafer stage 43. This is a case in which the wafer stage 43, serving as a third holding unit, is moved so as to bring the wafer W closer to the dies D. Accordingly, when the wafer W is moved in the +Z direction by driving the wafer stage 43 to perform a bonding process, a method of moving a bonding head is advantageous. Specifically, a method of retracting a bonding head by moving the bonding head in the +Z direction and a method of retracting a bonding head by moving the bonding head along the X-Y plane are advantageous. FIG. 6 is a diagram illustrating an example in which a bonding head is retracted from the wafer W in the Z-axis direction. This is a retraction method that can be achieved by driving the bonding head to be retracted in the +Z direction, or by driving only a bonding head used for bonding in the-Z direction to perform a bonding process. FIG. 7 is a diagram illustrating an example in which a bonding head is retracted from the wafer W along the X-Y plane. This is a retraction method that can be achieved by moving a bonding head along the X-Y plane to retract the bonding head. The X-Y plane is a plane parallel to a plane on which the bonding target region on the wafer W (the bonding target object) is disposed, and the Z-axis direction is perpendicular to the X-Y plane.

Next, the wafer stage 43 is driven by the driving mechanism 435 such that the die D is positioned at a bonding target region (bonding target portion) on the wafer W (S1010). Step S1010 may be performed by driving a bonding head.

Next, the die D is bonded to the bonding target region on the wafer W (S1011, bonding step). As an operation for bonding, the bonding head 422 may move up and down, or the wafer stage 43 or the wafer chuck 432 may move up and down. In other words, the driving mechanism may be driven such that the relative position (spacing) between the die D held by the bonding head 422 and the wafer W held by the wafer chuck 432 changes. In the bonding step of step S1006, the plurality of dies D held by the plurality of bonding heads 422 are bonded to the plurality of bonding target regions of the wafer W by changing the relative positions between the plurality of bonding heads 422 and the wafer W. In contrast, in step S1011, the bonding head retracted in step S1009 is positioned at a retraction position; accordingly, the retracted bonding head and the die D held by the bonding head do not come into contact (interfere with) other members during the bonding operation in step S1011. In other words, the control performed in step S1011 (and step S1009) is the second control.

The second control controls the bonding such that the first die held by the first bonding head does not come into contact with the wafer W while the second die held by the second bonding head is in contact with the wafer W. The control unit CNT performs the second control such that the dies D are bonded to the respective bonding target regions using combinations of bonding heads and bonding target regions based on a relative amount of movement between the bonding head group 422 and the wafer stage 43.

Next, the control unit CNT determines whether any one of the plurality of bonding heads holds a die D (S1012). If none of the plurality of bonding heads holds a die D, the process proceeds to step S1007. If any one of the plurality of bonding heads holds a die D, the process proceeds to step S1013. In step S1013, the control unit CNT determines whether bonding heads need to be retracted. For example, when only one of the plurality of bonding heads holds a die D, and a bonding process can be properly performed without retracting the bonding heads that do not hold a die D, the control unit CNT determines that retraction is not required. Alternatively, when the control unit CNT determines that each of the plurality of bonding heads holds a die D and that these bonding heads can perform simultaneous bonding, the control unit CNT determines that retraction is not required. This determination is the same as the determination in step S1004.

If it is determined in step S1013 that retraction is required, the process proceeds to step S1009. If it is determined in step S1013 that retraction is not required, the process proceeds to step S1010.

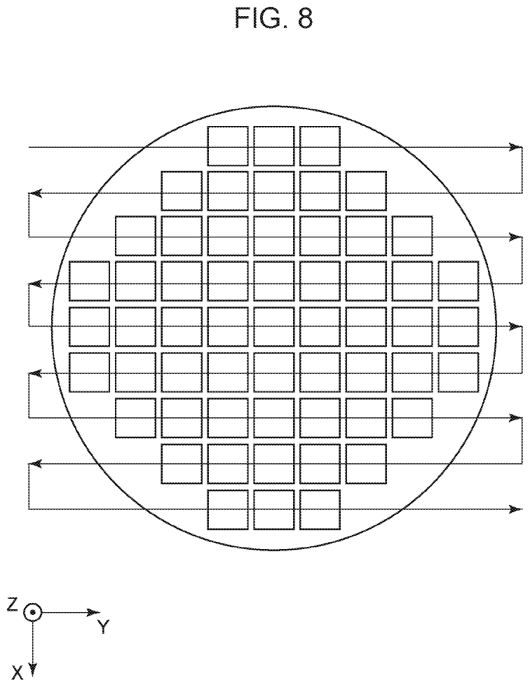

Next, the process of determining combinations of bonding heads and bonding target regions on the wafer W in step S3001 will be described. FIG. 8 is a diagram illustrating an example of the bonding order of the bonding target regions on the wafer W. In the example shown in FIG. 8, the bonding target regions arranged in the-X direction and -Y direction are first subjected to a bonding process in the order indicated by the arrows.

The control unit CNT may obtain layout information by receiving information on the layout of the bonding target regions from another information processing apparatus, the layout information may be stored in advance in a storage unit, or the layout information may be obtained by receiving an input from an operator.

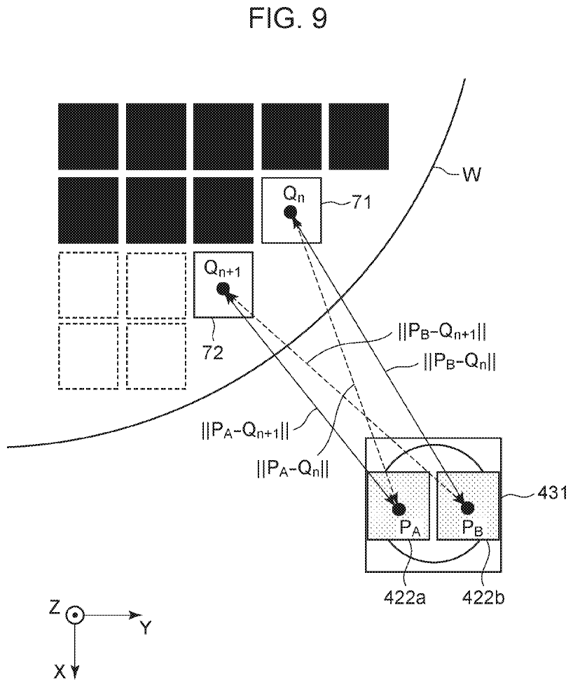

FIG. 9 is a schematic diagram illustrating bonding target regions on the wafer W, and the first bonding head 422a and the second bonding head 422b disposed over the die measuring unit 431 for measuring the dies D. The first bonding head 422a and the second bonding head 422b each hold a die D. In this state, the die measuring step in step S1003 has been completed, and the first bonding head 422a and the second bonding head 422b are positioned over the die measuring unit 431. In the example shown in FIG. 9, a single die measuring unit 431 measures the first die held by the first bonding head 422a and the second die held by the second bonding head 422b. However, two die measuring units may be provided, each of which measures a die D held by a corresponding bonding head.

The black regions on the wafer W in FIG. 9 are bonding target regions (bonding-completed regions) in which bonding of a die D has been completed. The white regions on the wafer W are bonding target regions (bonding-to-be-completed regions) in which bonding of a die D has not been completed. When the dies D are sequentially bonded to the bonding target regions, as illustrated in FIG. 8, the next bonding process is performed on a first bonding target region 71 and a second bonding target region 72, and bonding is performed on these bonding target regions 71 and 72 by the first bonding head 422a and the second bonding head 422b, respectively. In such an arrangement of the bonding target regions, when the allowable driving range of the bonding heads 422 in the X-Y plane is small, it is determined in step S1004 that simultaneous bonding by the plurality of bonding heads 422 is not possible. In other words, when the plurality of bonding heads used for bonding cannot be simultaneously positioned on the corresponding bonding target regions, it is determined that simultaneous bonding is not possible. Furthermore, even when the plurality of bonding heads can be simultaneously positioned on the plurality of bonding target regions, it may also be determined in step S1004 that simultaneous bonding is not possible as described above.

The bonding target regions to be bonded by the plurality of bonding heads are determined in the same manner as in the determination in step S1004. In other words, in the example shown in FIG. 9, target regions to be bonded are determined as the first bonding target region 71 and the second bonding target region 72 from among the plurality of bonding target regions on the wafer W, based on the same criteria as those used in the determination in step S1004. Specifically, target regions to be bonded are determined based on at least one of arrangement information on the bonding target regions of the wafer W, information on the circuit patterns formed in the bonding target regions, information on the types of the dies D, information on the quality, information on the thickness, and information on bonding history. The information on quality includes information on the quality of at least one of the wafer W and the dies D. The information on thickness includes information on the thickness of at least one of the wafer W and the dies D.

Here, consider a case in which the first die held by the first bonding head 422a and the second die held by the second bonding head 422b are of the same type, and either the first die or the second die may be bonded to the first bonding target region and the second bonding target region. Since it is determined in step S1004 that simultaneous bonding is not possible, the first bonding head 422a and the second bonding head 422b perform bonding operations at different timings. In this case, a first combination is conceivable in which the first die held by the first bonding head 422a is bonded to the first bonding target region 71, and the second die held by the second bonding head 422b is bonded to the second bonding target region 72. As another combination, a second combination is conceivable in which the first die held by the first bonding head 422a is bonded to the second bonding target region 72, and the second die held by the second bonding head 422b is bonded to the first bonding target region 71. In the present embodiment, combinations of bonding heads and bonding target regions are determined based on the relative amount of movement between the bonding head group 422 and the wafer stage 43 when the dies D are bonded to the plurality of bonding target regions using the plurality of bonding heads.

In FIG. 9, PA represents the center coordinate of the first bonding head 422a, PB represents the center coordinate of the second bonding head 422b, Qn represents the center coordinate of the first bonding target region 71, and Qn+1 represents the center coordinate of the second bonding target region 72. These center coordinates represent the respective center positions of the target objects on the X-Y plane. Although the present embodiment is described using the center coordinates as an example, the coordinates of any specific positions may be used; for example, the coordinates of end portions may be used.

A shorter relative amount of movement between the bonding head group 422 and the wafer stage 43 is advantageous in terms of throughput when the first bonding head 422a and the second bonding head 422b perform bonding on the first bonding target region 71 and the second bonding target region 72. Here, the relative amount of movement between the bonding head group 422 and the wafer stage 43 refers to an amount of movement in the X-Y plane. In the present embodiment, combinations of bonding heads and bonding target regions are determined by the following method.

In a first combination, a relative amount of movement between the bonding head group 422 and the wafer stage 43 when the first bonding head 422a performs bonding on the first bonding target region 71 is defined as ∥PA−Qn∥. A relative amount of movement between the bonding head group 422 and the wafer stage 43 when the second bonding head 422b performs bonding on the second bonding target region 72 is defined as ∥PB−Qn+1∥.

In a second combination, a relative amount of movement between the bonding head group 422 and the wafer stage 43 when the first bonding head 422a performs bonding on the second bonding target region 72 is defined as ∥PA−Qn+1∥. A relative amount of movement between the bonding head group 422 and the wafer stage 43 when the second bonding head 422b performs bonding on the first bonding target region 71 is defined as ∥PB−Qn∥. These relative amounts of movement on the X-Y plane are obtained, for example, from the respective center coordinate values of the target objects on the X-Y plane.

At this time, the evaluation value of the first combination is expressed by Eq. (1), and the evaluation value of the second combination is expressed by Eq. (2). These evaluation values are obtained by squaring the relative amount of movement when each bonding head performs a bonding process on a corresponding bonding target region, and summing the squared relative amounts of movement of all the bonding heads. Although the present embodiment describes an example in which the evaluation values are calculated for the bonding head group 422 including two bonding heads and combinations of bonding heads and bonding target regions are determined, the number of bonding heads may be three or more. By using a least-squares method, differences among the evaluation values can be amplified for evaluation. When the differences can be evaluated without squaring, the sum of the relative amounts of movement may be used.

Math. 1

∥P_{A}−Qₙ∥²+∥P_{B} −Qₙ₊₁∥² Eq. (1)

Math. 2

∥P_{B}−Qₙ∥²+∥P_{A}−Qₙ₊₁∥² Eq. (2)

A combination of a bonding head and a bonding target region having the smallest evaluation value among these evaluation values is selected. By using such a combination of a bonding head and a bonding target region, relative amounts of movement between the bonding head group 422 and the wafer stage 43 during the bonding process can be reduced, thereby improving throughput.

In the example shown in FIG. 9, based on the above-described evaluation values, it is determined that the first bonding head 422a performs bonding on the second bonding target region 72 and the second bonding head 422b performs bonding on the first bonding target region 71.

Next, the determination of the bonding order in step S3002 will be described. By determining the bonding order in addition to determining combinations of the bonding head group 422 and the plurality of bonding target regions based on the relative amount of movement in the X-Y plane between the bonding head group 422 and the wafer stage 43, throughput can be further improved.

In determining the bonding order, a bonding time is calculated for each possible bonding order when a bonding process is performed using the combinations of bonding heads and bonding target regions determined in step S3001. Here, the bonding time is, for example, a driving time required for relative movement between the bonding head group 422 and the wafer stage 43. In the example shown in FIG. 9, it is determined in step S3001 that the first bonding head 422a performs bonding on the second bonding target region 72 and the second bonding head 422b performs bonding on the first bonding target region 71. In this case, there are two possible bonding orders, namely, a first bonding order and a second bonding order. In the first bonding order, the first bonding head 422a performs a bonding process on the second bonding target region 72, and then the second bonding head 422b performs a bonding process on the first bonding target region 71.

In the second bonding order, the second bonding head 422b performs a bonding process on the first bonding target region 71, and then the first bonding head 422a performs a bonding process on the second bonding target region 72. The number of possible bonding orders is cPc=c! (the factorial of c), where c is the number of bonding heads. Accordingly, a bonding time is calculated for each of the c! bonding orders. The bonding start time is, for example, a time at which a relative position between the bonding head group 422 and the wafer stage 43 starts to change from a state in which the bonding head group 422 is disposed at a predetermined start reference position (for example, over the die measuring unit 431). The bonding end time is, for example, a time at which the plurality of bonding heads have completed bonding the dies D to the plurality of bonding target regions. This is a time until bonding of the dies D held by the plurality of bonding heads to the plurality of bonding target regions is completed. Alternatively, the bonding end time is a time at which the bonding head group 422 has completed moving to a predetermined end reference position (for example, a predetermined position over the die measuring unit 431 or the pick-up unit 3).

The bonding time is calculated, for example, based on at least one of the size of the die D to be bonded, the size of the bonding head, the moving speed of the wafer stage 43, and the moving speed of the bonding head. Here, the moving speed of the wafer stage 43 and the moving speed of the bonding head are collectively referred to as the relative moving speed between the bonding head group 422 and the wafer stage 43 (the holding unit). Here, the size of the die D and the size of the bonding head refer to the respective areas of the die D and the bonding head on the X-Y plane. The larger the die D and the bonding head, the longer the time required to position the die D directly above the bonding target region (that is, the greater the relative amount of movement between the wafer stage 43 and the bonding head group 422). When the die D is large, the amount of movement required for the bonding head to retract increases, and accordingly, the bonding time becomes longer. In other words, calculating the bonding time based on the size of the die D includes calculating the bonding time based on the retraction time of the bonding head. Furthermore, as the moving speeds of the wafer stage 43 and the bonding head increase, the bonding time can be reduced. The bonding time is calculated using a calculation formula, a prediction model, or simulation.

After calculating a bonding time for each possible bonding order, a bonding order having the shortest bonding time is determined as a bonding order to be used in the bonding process.

An example will be described with reference to FIG. 9. When bonding is performed in the first bonding order, the first bonding head 422a first performs bonding on the second bonding target region 72. At this time, the relative amount of movement between the bonding head group 422 and the wafer stage 43 is represented by ∥PA−Qn+1∥. In this case, since no bonding target region is present directly below the second bonding head 422b and there is no risk of interference, the second bonding head 422b does not need to be retracted during the bonding process performed by the first bonding head 422a. In other words, the retraction time of the second bonding head 422b can be reduced. Next, for a bonding process by the second bonding head 422b, the wafer stage 43 and the bonding head group 422 are moved relative to each other by one column in the X-axis direction such that the first bonding target region 71 is positioned directly below the second bonding head 422b. While the second bonding head 422b performs bonding on the first bonding target region 71, a bonding target region to which a die D has already been bonded is present directly below the first bonding head 422a. In this case, based on the thickness of the bonded die D and/or the bonding history, it is determined whether the first bonding head 422a interferes with the wafer W during the bonding process performed by the second bonding head 422b. When the first bonding head 422a interferes, the first bonding head 422a needs to be retracted, and when the first bonding head 422a does not interfere, the first bonding head 422a does not need to be retracted. In other words, in the first bonding order, the retraction time of the second bonding head 422b can be omitted, and the retraction time of the first bonding head 422a may also be omitted. The relative amount of movement of the bonding target region is obtained by adding, to ∥PA−Qn+1∥, an amount of movement corresponding to one column in the X-axis direction.

When bonding is performed in the second bonding order, the second bonding head 422b first performs bonding on the first bonding target region 71. At this time, the relative amount of movement between the bonding head group 422 and the wafer stage 43 is represented by ∥PB−Qn∥. In this case, a bonding target region is present directly below the first bonding head 422a, and the first bonding head 422a itself holds a die D; therefore, there is a risk of interference. Accordingly, the first bonding head 422a needs to be retracted during the bonding process performed by the second bonding head 422b.

In other words, a retraction time for the first bonding head 422a is required. Next, for a bonding process by the first bonding head 422a, the wafer stage 43 and the bonding head group 422 are moved relative to each other by one column in the X-axis direction such that the second bonding target region 72 is positioned directly below the first bonding head 422a. While the first bonding head 422a performs bonding on the second bonding target region 72, no bonding target region is present directly below the first bonding head 422a; therefore, there is no risk of interference. Accordingly, the second bonding head 422b does not need to be retracted during the bonding process performed by the first bonding head 422a. In other words, a retraction time for the second bonding head 422b can be reduced. Thus, in the second bonding order, a retraction time for the first bonding head 422a is required, and a retraction time for the second bonding head 422b can be omitted. The relative amount of movement of the bonding target region is obtained by adding, to ∥PB−Qn∥, an amount of movement corresponding to one column in the X-axis direction.

Thus, from the viewpoint of retraction time, the first bonding order is more advantageous than the second bonding order. The relative amount of movement in the first bonding order is obtained by adding, to ∥PA−Qn+1∥, an amount of movement corresponding to one column in the X-axis direction, and the relative amount of movement in the second bonding order is obtained by adding, to ∥PB−Qn∥, an amount of movement corresponding to one column in the X-axis direction. In other words, in the second bonding order, a reciprocating movement occurs in the X-axis direction, and therefore the amount of movement in the X-axis direction increases, resulting in a longer movement time. Accordingly, the first bonding order is more advantageous than the second bonding order also from the viewpoint of the amount of movement. From these viewpoints, in the example shown in FIG. 9, the control unit CNT determines that bonding is to be performed in the first bonding order.

The method of the present embodiment is not limited to the above-described example. Alternatively, the bonding target region may be divided into sections in accordance with the number of bonding heads included in the bonding head group 422, and combinations of bonding target regions and bonding heads may be determined for each section. Furthermore, a bonding order may be determined based on the combinations of bonding target regions and bonding heads determined for each section.

### Second Embodiment

The present embodiment relates to a method for manufacturing an article using the bonding apparatus BD described above.

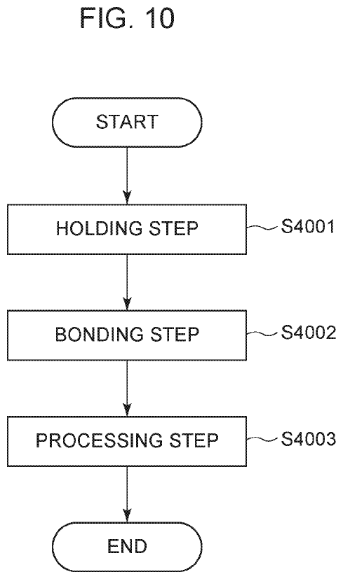

FIG. 10 is a flowchart illustrating the method for manufacturing an article according to the present embodiment. First, each of the plurality of bonding heads included in the bonding head group 422 holds a die D (S4001, holding step). Next, dies D are bonded to corresponding ones of the plurality of bonding target regions on the wafer W (S4002, bonding step). Then, the wafer W to which the dies D have been bonded in the bonding step is processed (S4003, processing step).

In the bonding step, bonding is performed using combinations of bonding heads and bonding target regions based on the relative amount of movement between the bonding head group 422 and holding units that hold the wafer W when the plurality of bonding heads bond the dies D to the plurality of bonding target regions. Here, the relative amount of movement refers to an amount of movement in a plane (X-Y plane) parallel to a surface of the wafer W having a plurality of bonding target regions.

Examples of articles manufactured by this manufacturing method include, but are not limited to, semiconductor integrated circuit (IC) devices, liquid crystal display elements, color filters, MEMSs, light-emitting devices (LEDs), sensors, and optical devices. According to the article manufacturing method of the present embodiment, throughput can be improved.

It is to be understood that the present disclosure is not limited to the above embodiments, and that various changes and modifications can be made without departing from the spirit and scope of the disclosure. Accordingly, the claims are appended to define the scope of the disclosure.

According to the present disclosure, a bonding apparatus that is advantageous in terms of throughput can be provided.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-064310, filed Apr. 9, 2025, which is hereby incorporated by reference herein in its entirety.

What is claimed is:

1. A bonding apparatus configured to bond dies to corresponding ones of a plurality of bonding target regions on a wafer, the bonding apparatus comprising:
a bonding head group including a plurality of bonding heads configured to hold the dies;
a holding unit configured to hold the wafer; and
a control unit configured to control a relative position between the bonding head group and the holding unit,
wherein the control unit controls bonding such that the plurality of bonding heads included in the bonding head group bond the dies to corresponding ones of the plurality of bonding target regions based on combinations of bonding heads and bonding target regions according to a relative amount of movement between the bonding head group and the holding unit in a plane parallel to a surface of the wafer having the plurality of bonding target regions.

2. The bonding apparatus according to claim 1,
wherein the plurality of bonding target regions includes a first bonding target region and a second bonding target region,
wherein the bonding head group includes a first bonding head and a second bonding head, and
wherein the control unit controls bonding such that, when a first relative amount of movement, which is a relative amount of movement when the first bonding head performs bonding on the first bonding target region and the second bonding head performs bonding on the second bonding target region, is smaller than a second relative amount of movement, which is a relative amount of movement when the first bonding head performs bonding on the second bonding target region and the second bonding head performs bonding on the first bonding target region, the first bonding head performs bonding on the first bonding target region and the second bonding head performs bonding on the second bonding target region.

3. The bonding apparatus according to claim 2,
wherein the first relative amount of movement is a sum of a relative amount of movement when the first bonding head moves to a position over the first bonding target region and a relative amount of movement when the second bonding head moves to a position over the second bonding target region, and
wherein the second relative amount of movement is a sum of a relative amount of movement when the first bonding head moves to a position over the second bonding target region and a relative amount of movement when the second bonding head moves to a position over the first bonding target region.

4. The bonding apparatus according to claim 2,
wherein the first relative amount of movement is a sum of a value obtained by squaring a relative amount of movement when the first bonding head moves to a position over the first bonding target region and a value obtained by squaring a relative amount of movement when the second bonding head moves to a position over the second bonding target region, and
wherein the second relative amount of movement is a sum of a value obtained by squaring a relative amount of movement when the first bonding head moves to a position over the second bonding target region and a value obtained by squaring a relative amount of movement when the second bonding head moves to a position over the first bonding target region.

5. The bonding apparatus according to claim 1, wherein a bonding target region to which a die is to be bonded by the bonding head group is determined based on at least one of arrangement information of the plurality of bonding target regions, information on circuit patterns formed in the bonding target regions, type information of the dies, quality information of the bonding target regions, quality information of the dies, thickness information of the wafer, thickness information of the dies, and bonding history information.

6. The bonding apparatus according to claim 1, wherein the control unit determines, based on the combinations, a bonding order for bonding dies to the plurality of bonding target regions using the plurality of bonding heads included in the bonding head group.

7. The bonding apparatus according to claim 1, wherein the control unit determines a bonding order based on a time required to bond the dies to corresponding ones of the plurality of bonding target regions using the plurality of bonding heads included in the bonding head group.

8. The bonding apparatus according to claim 7, wherein the time is a period from a time at which relative movement between the bonding head group and the holding unit starts, with the bonding head group being disposed at a predetermined start reference position, to a time at which bonding of the dies held by the plurality of bonding heads to the plurality of bonding target regions is completed.

9. The bonding apparatus according to claim 7, wherein the time is a period from a time at which relative movement between the bonding head group and the holding unit starts, with the bonding head group being disposed at a predetermined start reference position, to a time at which the bonding head group has completed moving to a predetermined end reference position.

10. The bonding apparatus according to claim 7, wherein the time is calculated based on at least one of size information of the dies respectively held by the plurality of bonding heads, size information of the plurality of bonding heads, and a relative moving speed between the bonding head group and the holding unit.

11. The bonding apparatus according to claim 7, wherein the time is calculated based on a time for the bonding head to be retracted.

12. The bonding apparatus according to claim 7, wherein the control unit calculates the time for each of a plurality of bonding orders and controls the bonding process to be performed in a bonding order having the shortest calculated time.

13. The bonding apparatus according to claim 1,
wherein the bonding head group includes a first bonding head and a second bonding head, and
wherein the control unit is configured to switch between
a first control configured to control bonding such that a period during which a first die held by the first bonding head is in contact with the bonding target region and a period during which a second die held by the second bonding head is in contact with the bonding target region overlap at least in part, and
a second control configured to control bonding such that the first die held by the first bonding head is prevented from coming into contact with the bonding target region while the second die held by the second bonding head is in contact with the bonding target region, and
wherein, in the second control, the control unit controls the bonding process such that the dies are bonded to corresponding ones of the plurality of bonding target regions based on combinations of bonding heads and bonding target regions according to a relative amount of movement between the bonding head group and the holding unit.

14. A bonding method for bonding dies to corresponding ones of a plurality of bonding target regions on a wafer, the bonding method comprising:
holding the dies using corresponding ones of a plurality of bonding heads included in a bonding head group; and
bonding the dies to corresponding ones of the plurality of bonding target regions,
wherein, in the bonding, the plurality of bonding heads bond the dies to corresponding ones of the plurality of bonding target regions based on combinations of bonding heads and bonding target regions according to a relative amount of movement between the bonding head group and a holding unit that holds the wafer in a plane parallel to a surface of the wafer having the plurality of bonding target regions.

15. The bonding method according to claim 14, further comprising:
determining a bonding target region to which a die is to be bonded by the bonding head group based on at least one of arrangement information of the plurality of bonding target regions, information on circuit patterns formed in the bonding target regions, type information of the dies, quality information of the bonding target regions, quality information of the dies, thickness information of the wafer, thickness information of the dies, and bonding history information.

16. The bonding method according to claim 14, further comprising:
determining a bonding order based on a time required to bond the dies to corresponding ones of the plurality of bonding target regions using the plurality of bonding heads.

17. A non-transitory computer-readable storage medium storing a program for causing a computer to execute the bonding method according to claim 14.

18. A method for manufacturing an article, the method comprising:
holding dies using corresponding ones of a plurality of bonding heads included in a bonding head group;
bonding the dies to corresponding ones of a plurality of bonding target regions on a wafer; and
processing the wafer to which the dies are bonded by the bonding,
wherein, in the bonding, the plurality of bonding heads bond the dies to corresponding ones of the plurality of bonding target regions based on combinations of bonding heads and bonding target regions according to a relative amount of movement between the bonding head group and a holding unit that holds the wafer in a plane parallel to a surface of the wafer having the plurality of bonding target regions.
